(19) United States
(12) Patent Application Publication
(10) Pub. No.: US 2017/0198551 A1
(43) Pub. Date: Jul. 13, 2017

(54) COMPOSITES CONTAINING ALIGNED CARBON NANOTUBES, METHODS OF MANUFACTURE AND APPLICATIONS THEREOF

(71) Applicants: Zhou Zhou, Houston, TX (US); Valery N. Khabashesku, Houston, TX (US); Othon Do Rego Monteiro, Houston, TX (US)

(72) Inventors: Zhou Zhou, Houston, TX (US); Valery N. Khabashesku, Houston, TX (US); Othon Do Rego Monteiro, Houston, TX (US)

(73) Assignee: Baker Hughes Incorporated, Houston, TX (US)

(21) Appl. No.: 14/993,122

(22) Filed: Jan. 12, 2016

(51) Int. Cl. E21B 41/00; C25D 5/48; C23C 16/26; C25D 5/18; C01B 31/02; C09D 5/08

(52) U.S. Cl. CPC E21B 41/00; C01B 31/0253; C01B 31/0226; C09D 5/084; C23C 16/26; C25D 5/18; C25D 5/48

(57) ABSTRACT

A method of protecting an article from a downhole environment comprises growing carbon nanotubes on a surface of a substrate via a chemical vapor deposition process; the carbon nanotubes having a first end formed on the surface of the substrate and a second end extending away from the substrate; filling the spaces among the carbon nanotubes with a metallic material or a polymeric material forming a coated article; and exposing the coated article to a downhole environment.

### BACKGROUND

The disclosure is directed to composites containing aligned carbon nanotubes, methods of manufacture, and applications thereof, and in particular to coatings containing metals/metal alloys and aligned carbon nanotubes and their use in downhole applications.

A downhole environment such as an oil or gas well in an oilfield or undersea formations may expose equipment used downhole to severe conditions of temperature, pressure, or corrosiveness. Where an equipment has a rubber, plastic, or metal part, these harsh environmental conditions can cause swelling, corrosion, erosion of the parts, thus affecting the integrity or performance of the equipment.

Advances in methods and materials to ameliorate environmental effects on downhole articles are well received by the industry.

### BRIEF DESCRIPTION

In an embodiment, a method of manufacturing an article is provided. The method includes growing carbon nanotubes on a surface of a substrate via a chemical vapor deposition process; the carbon nanotubes having a first end formed on the surface of the substrate and a second end extending away from the substrate; and filling the spaces among the carbon nanotubes with a metallic material or a polymeric material forming the composite.

In another embodiment, a composite comprises: a substrate having a surface that is configured for exposure to a well fluid; and a coating disposed on the surface of the substrate; the coating comprising carbon nanotubes grown on the surface of the substrate, the carbon nanotubes having a first end formed on the surface of the substrate and a second end extending away from the substrate; and a metallic or polymeric material filled in the spaces among the carbon nanotubes.

A method of protecting an article from a downhole environment comprises growing carbon nanotubes on a surface of the article via a chemical vapor deposition process; the carbon nanotubes having a first end formed on the surface of the substrate and a second end extending away from the substrate; filling the spaces among the carbon nanotubes with a metallic material or a polymeric material forming a coated article; and exposing the coated article to a downhole environment.

### BRIEF DESCRIPTION OF THE DRAWINGS

Referring now to the drawings wherein like elements are numbered alike in the several Figures:

FIG. 1 illustrates carbon nanotubes grown on a substrate according to an embodiment of the disclosure;

FIG. 2 is a scanning electron microscope (SEM) image of carbon nanotubes grown on a substrate;

FIG. 3 illustrates the infiltration of metal ions or metal alloy ions into the spaces among carbon nanotubes grown on a substrate;

FIG. 4 illustrates the deposition of a metal or metal alloy in the spaces among carbon nanotubes grown on a substrate;

FIG. 5 illustrates the formation of a coating on a substrate surface;

FIGS. 6A-6E are SEM images of a composite comprising a metal or metal alloy infiltrated into the spaces among aligned carbon nanotubes; and

FIG. 7 shows a surface coating after the metal or metal alloy of the coating is etched exposing an end of the carbon nanotubes.

### DETAILED DESCRIPTION

To improve mechanical properties of coatings, carbon nanotubes (CNTs) can be dispersed in a coating composition and coated on a substrate. In a coating made by such a method, the carbon nanotubes are randomly oriented; and there is no direct bonding between the carbon nanotubes and the substrate. Further, in many instances there is little control over the loading level of the carbon nanotubes in the final coating. In addition, the dispersion of carbon nanotubes in a coating composition usually requires a dispersing agent, which introduces unnecessary materials and may potentially lower the strength of the coating.

Methods and articles are provided that are effective to control the composition of the coating. Instead of dispersing carbon nanotubes in a coating composition, the carbon nanotubes are grown on a surface of a substrate through a chemical vapor deposition (CVD) process. After carbon nanotubes are grown to a desirable length, a polymeric or a metallic material can be deposited in and completely fill the spaces among carbon nanotubes forming a coating.

In the methods disclosed herein, no dispersing agent is required. The density of the carbon nanotubes can be tuned by adjusting the conditions of the chemical vapor deposition process, leading to a coating having higher amount of carbon nanotubes than the coating made by a dispersion method. In addition, the carbon nanotubes grown on a substrate through a chemical vapor deposition process have improved adherence to the substrate allowing for the formation of a secured coating layer. Further, the carbon nanotubes in the coating are vertically aligned, which makes it easy to expose the end of the carbon nanotubes to adjust the surface properties of the coating. In particular, the polymeric or the metallic material can be partially removed exposing the end of the carbon nanotubes extending away from the substrate. Due to the super-hydrophobicity of carbon nanotubes, such a coating surface can also be hydrophobic. The etching depth can be controlled to realize desired length of CNT ends. With the tunable CNT density and the exposed length, the super-hydrophobicity of the coated surface can be customized for different applications.

A three dimensional structure formed by the method can be used as a protective coating, combing the advantages from both the polymeric or metallic coatings and carbon nanotubes. The structure provides corrosion resistance, erosion resistance, high hardness and tunable super-hydrophobicity. Moreover the length of the carbon nanotubes grown on a substrate can be tuned. Thus the methods disclosed herein can also be used to form a composite having various thickness.

The carbon nanotubes can be deposited on a surface of a substrate by chemical vapor deposition. In the process, a carbon source gas is thermally decomposed or reacted in the presence of a catalyst forming carbon nanotubes. The chemical vapor deposition includes plasma assistant chemical vapor deposition.

The carbon source includes, but is not limited to, C₁₋₁₀ hydrocarbon, which can be in a gas, solid, or liquid form at room temperature as long as it can be converted to a gas under the deposition pressure and temperature. As used herein, “hydrocarbon” refers broadly to a compound comprising carbon and hydrogen, optionally with 1 to 3 heteroatoms, for example, oxygen, nitrogen, halogen, silicon, sulfur, or a combination thereof. Exemplary carbon source includes methane, acetylene, ethylene, cyclohexane, camphor, benzene, xylene, ethanol, and carbon monoxide. Preferably, the carbon source is a linear hydrocarbon such as methane, ethylene, acetylene, which can produce relatively straight carbon nanotubes.

The growth of carbon nanotubes may be directly on a surface of the substrate where the substrate comprises a metal such as Fe or in association with a suitable catalyst provided on a surface of the substrate. The catalyst includes Fe, Co, Ni, Cu, Au, Ag, Pt, or Pd. When a catalyst is provided on a surface of the substrate, the catalyst can be present in the form of a thin film or nanodots deposited on the substrate surface.

The growth temperature is about 700° C. to about 1000° C. The pressure may be atmospheric pressure, a subatmospheric pressure, or an ultrahigh vacuum. The characteristics such as density, length, and diameter of the carbon nanotubes may be controlled by factors such as growth temperature, precursor, gas supply, the nature of the substrate surface, and the catalyst used.

The carbon nanotubes grown on the substrate include mainly multi-wall carbon nanotubes. The carbon nanotubes may have an outer diameter of about 5 to 10 nm and a length of about 50 μm to about 1.5 cm. The density of the carbon nanotube is about 1 wt % to about 3 wt % based on the weight of carbon occupying the same volume of the carbon nanotubes. Advantageously, the carbon nanotubes are substantially perpendicular to the surface of the substrate and are vertically aligned.

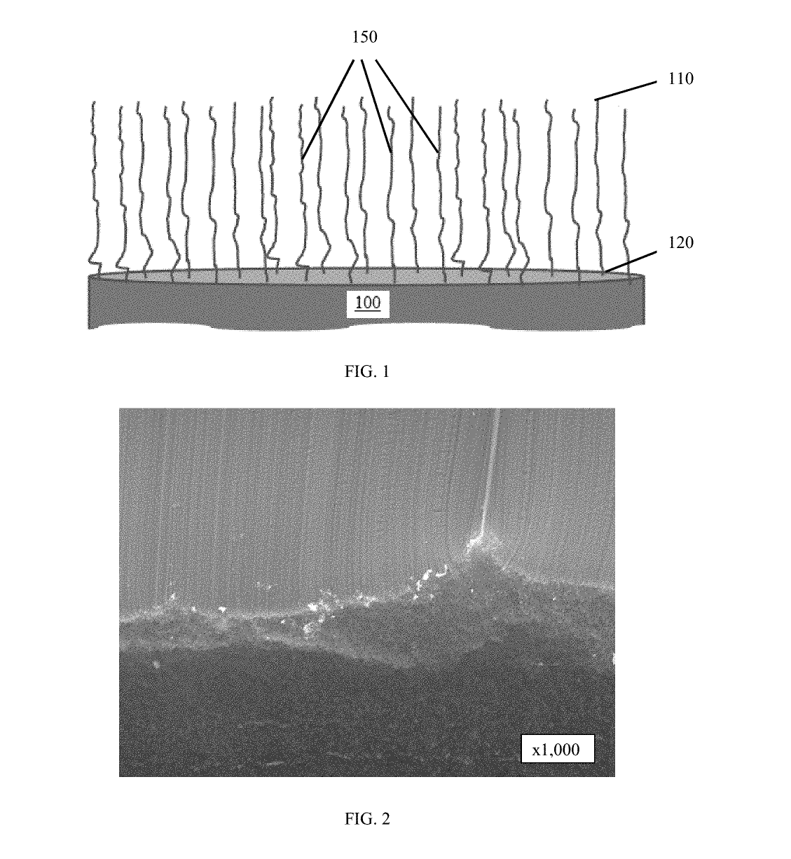

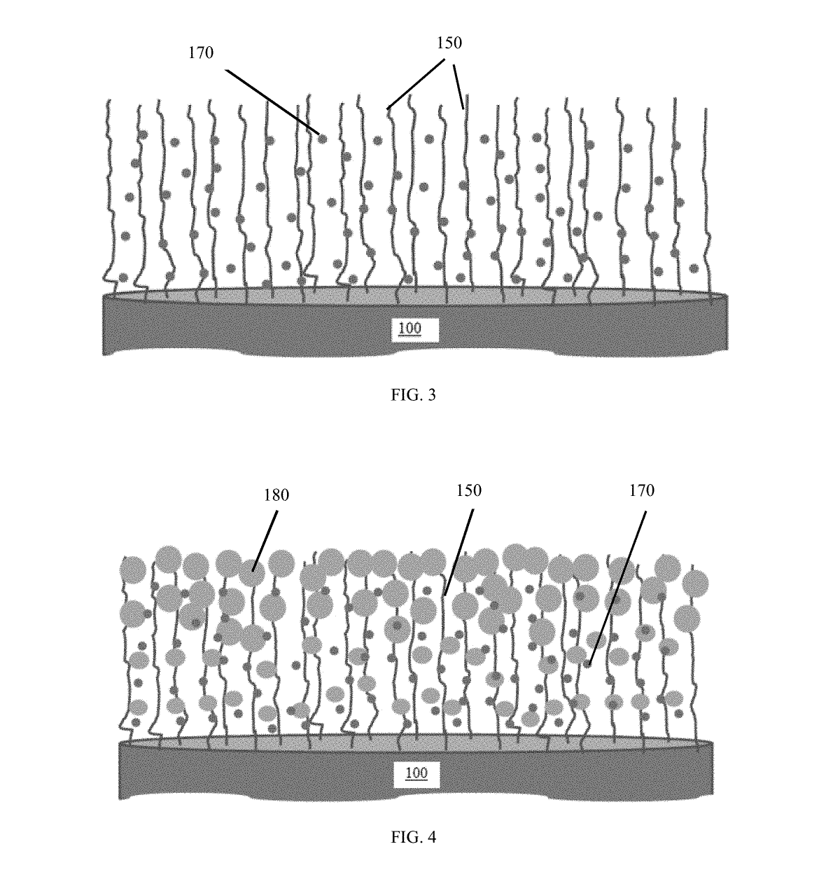

FIG. 1 illustrates carbon nanotubes 150 grown on a substrate 100 according to an embodiment of the disclosure. The nanotubes 150 have a first end 120 formed on a surface of substrate 100 and a second end 110 extending away from the substrate 100. In FIG. 1, the carbon nanotubes 150 are substantially straight and vertically aligned. FIG. 2 is a scanning electron microscope (SEM) image of carbon nanotubes grown on a substrate;

The substrate can be a metal or a ceramic material or a polymer, or a combination thereof. It can be used without surface processing or can be processed, including chemically, physically, or mechanically treating the substrate. For example, the substrate can be treated to roughen or increase a surface area of the substrate. A surface of the substrate can also be cleaned to remove contaminants through chemical and/or mechanical means.

The metal of the substrate includes elements from Group 1 to Group 12 of the periodic table, alloys thereof, or a combination thereof. Exemplary metals are magnesium, aluminum, titanium, manganese, iron, cobalt, nickel, copper, molybdenum, tungsten, palladium, chromium, ruthenium, gold, silver, zinc, zirconium, vanadium, silicon, or a combination thereof, including alloys thereof. Metal alloys include, for example, an aluminum-based alloy, magnesium-based alloy, tungsten-based alloy, cobalt-based alloy, iron-based alloy, nickel-based alloy, cobalt and nickel-based alloy, iron and nickel-based alloy, iron and cobalt-based alloy, copper-based alloy, and titanium-based alloy. As used herein, the term “metal-based alloy” means a metal alloy wherein the weight percentage of the specified metal in the alloy is greater than the weight percentage of any other component of the alloy, based on the total weight of the alloy. Exemplary metal alloys include steel, nichrome, brass, pewter, bronze, invar, inconel, hastelloy, MgZrZn, MgAlZn, AlCuZnMn, and AlMgZnSiMn.

In an embodiment, the substrate comprises one or more of the following: copper; nickel; chromium; iron; titanium; an alloy of copper; an alloy of nickel; an alloy of chromium; an alloy of iron; or an alloy of titanium. Exemplary alloys include steel, nickel-chromium based alloys such as INCONEL, and nickel-copper based alloys such as Monel alloys. Nickel-chromium based alloys can contain about 40-75% of Ni and about 10-35% of Cr. The nickel-chromium based alloys can also contain about 1 to about 15% of iron. Small amounts of Mo, Nb, Co, Mn, Cu, Al, Ti, Si, C, S, P, B, or a combination comprising at least one of the foregoing can also be included in the nickel-chromium based alloys. Nickel-copper based alloys are primarily composed of nickel (up to about 67%) and copper. The nickel-copper based alloys can also contain small amounts of iron, manganese, carbon, and silicon.

The ceramic is not particularly limited and can be selected depending on the particular application of the substrate that has been coated with the carbon composite coating. Examples of the ceramic include an oxide-based ceramic, nitride-based ceramic, carbide-based ceramic, boride-based ceramic, silicide-based ceramic, or a combination thereof. In an embodiment, the oxide-based ceramic is silica (SiO₂) or titania (TiO₂). The oxide-based ceramic, nitride-based ceramic, carbide-based ceramic, boride-based ceramic, or silicide-based ceramic can contain a nonmetal (e.g., oxygen, nitrogen, boron, carbon, or silicon, and the like), metal (e.g., aluminum, lead, bismuth, and the like), transition metal (e.g., niobium, tungsten, titanium, zirconium, hafnium, yttrium, and the like), alkali metal (e.g., lithium, potassium, and the like), alkaline earth metal (e.g., calcium, magnesium, strontium, and the like), rare earth (e.g., lanthanum, cerium, and the like), or halogen (e.g., fluorine, chlorine, and the like).

In an embodiment, the substrate is a polymer substrate. The polymer substrate can be a thermoset polymer, thermoplastic polymer, or a combination thereof. The polymer substrate can be a blend of polymers, copolymers, terpolymers, or a combination thereof. The polymer substrate can also be an oligomer, a homopolymer, a copolymer, a block copolymer, an alternating block copolymer, a random polymer, a random copolymer, a random block copolymer, a graft copolymer, a star block copolymer, a dendrimer, or the like, or a combination thereof.

Exemplary polymer substrates include epoxies, ethylene propylene diene rubber, ethylene propylene diene monomer rubber, melamines, polyacetals, polyacrylamides, polyacrylics such as polyacrylic acid, polyacrylonitriles, polyamides, including polyamideimide, polyarylene ethers, polyarylene sulfides, polyarylene sulfones, polybenzoxazoles, polybenzothiazole, polybutadienes and copolymers thereof, polycarbonates, polycarbonate esters, polyether ketones, polyether ether ketones, polyether ketone ketones, polyethersulfones, polyesters, polyimides such as polyetherimides, polyisoprenes and copolymers thereof, polyolefins such a polyethylene and copolymers thereof, polypropylene and copolymers thereof, and polytetrafluoroethylene, polyphosphazenes, poly(alkyl) (meth)acrylates, polystyrenes and copolymers thereof, rubber-modified polystyrenes such as acrylonitrile-butadiene-styrene, styrene-ethylene-butadiene, and methyl methacrylate-buadiene-styrene, polyoxadiazoles, polysilazanes, polysulfones, polysulfonamides, polyvinyl acetates, polyvinyl chlorides, polyvinyl esters, polyvinyl ethers, polyvinyl halides, polyvinyl nitriles, polyvinyl thioethers, polyureas, polyurethanes, and silicones. A combination comprising at least one of the foregoing polymer substrates can be used.

In an embodiment, the polymer substrate is a fluoropolymer. Exemplary fluoropolymer polymer substrates include polytetrafluoroethylene, polyethylenetetrafluoroethylene, fluorinated ethylene propylene copolymer, perfluoroalkoxy polymer, polyvinylidene fluoride, polyvinylfluoride, polychlorotrifluoroethylene, polyethylenechlorotrifluoroethylene, chlorotrifluoroethylenevinylidene fluoride, perfluoroelastomer such as FFKM, tetrafluoroethylene-propylene elastomeric copolymers, perfluoropolyether, perfluorosulfonic acid, and the like. Other exemplary fluoropolymers include copolymers of vinylidene fluoride and hexafluoropropylene and terpolymers of vinylidene fluoride, hexafluoropropylene, and tetrafluoroethylene.

The substrate can have any shape. Exemplary shapes include a cube, sphere, cylinder, toroid, polygonal shape, helix, truncated shape thereof, or a combination thereof. The longest linear dimension of the substrate can be from 500 nm to hundreds of meters, without limitation.

After the nanotubes are grown to a desirable length, a polymeric or metallic material can be infiltrated into the carbon nanotube matrix and fill the spaces among the carbon nanotubes. The metallic material can be deposited on a metal or a ceramic substrate using a pulsed electrochemical deposition process. As used herein, the “pulsed electrochemical deposition” includes both pulse current deposition and pulse reverse current deposition. In a pulse current deposition process, deposition pulses alternate with deposition free diffusion periods. In a pulse reverse current deposition process, deposition pulses alternative with anodic counter pulses. By using a pulsed electrochemical deposition, the breaks between the deposition pulses allow for the metal ions in the electrolyte solution to diffuse into the spaces among different carbon nanotubes, which leads to a uniform development of a metal or metal alloy layer. Without wishing to be bound by theory, it is believed that in the intervals between pulses, metal ions can diffuse, and as a result, on the entire surface of the substrate thus a nearly uniform level of concentration at the beginning of each deposition pulse is obtained, which results in a homogenous development of a coating.

The metallic material in the coating includes Ni, Cu, Ag, Au, Sn, Zn, Fe, In, W, Ti, Co, Al, Mg, Cr, or Mo, or alloys of these metals, or a combination that includes at least one of these materials. In an embodiment, the metallic material includes an Ni-base alloy, Ti-based alloy, or Al-based alloy, where Ni, Ti, or Al is the majority constituent element by weight or atom percent. In another embodiment, the metallic material includes an Ni—B alloy, an Ni—P alloy, or a Ni—W alloy. Exemplary Ni—B alloys contain up to about 10 percent by weight of boron, the balance being Ni and trace impurities. Exemplary Ni—P alloy contains about 14 percent or less by weight P and the balance Ni and trace impurities. An Ni—W alloy (or W—Ni alloy) includes up to about 76 percent by weight of tungsten, and more particularly up to about 30 percent by weight of tungsten. In certain embodiments, this may include about 0.1 to about 76 percent by weight of tungsten, and more particularly about 0.1 to about 30 percent by weight of tungsten. The trace impurities will be those known conventionally for Ni and Ni alloys based on the methods employed to process and refine the constituent element or elements. Exemplary aluminum-based alloys include Al—Cu alloy, Al—Mn alloy, Al—Si alloy, Al—Mg alloy, Al—Mg—Si alloy, Al—Zn alloy, Al—Li alloy, Al—Cu—Mg—X alloy, Al—Zn—Mg—Cu—X, where X represents alloying elements including Zn, Mn, Si, Cr, Fe, Ni, Ti, V, Cu, Pb, Bi, and Zr.

In an exemplary embodiment, a coating comprising Ni as metallic material may be deposited by a pulsed electrochemical deposition using a nickel sulfate bath. In another exemplary embodiment, a coating comprising an Ni—P alloy as metallic material may be deposited by pulsed electrochemical deposition using a bath that includes nickel sulfate and sodium hypophosphite. In yet another exemplary embodiment, a coating comprising an Ni—W alloy as metallic material may be deposited by pulsed electrochemical deposition using a bath that includes nickel sulfate and sodium tungstate. Coatings that include a Ni—P alloy may be precipitation hardened to increase the hardness by annealing the coating sufficiently to cause precipitation of Ni₃P precipitates.

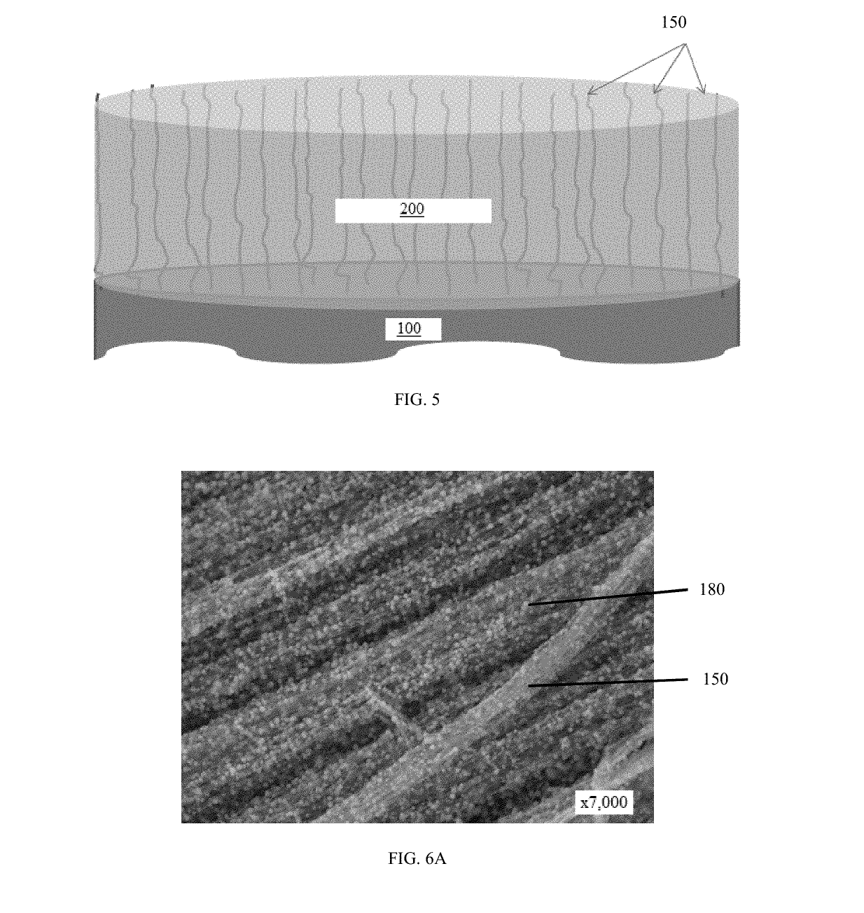

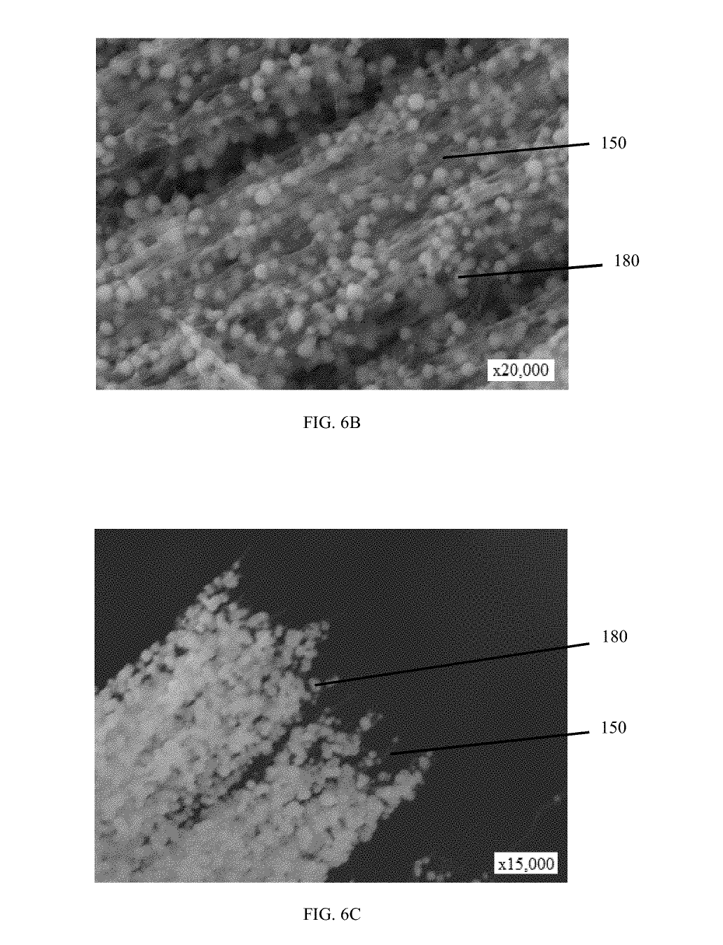

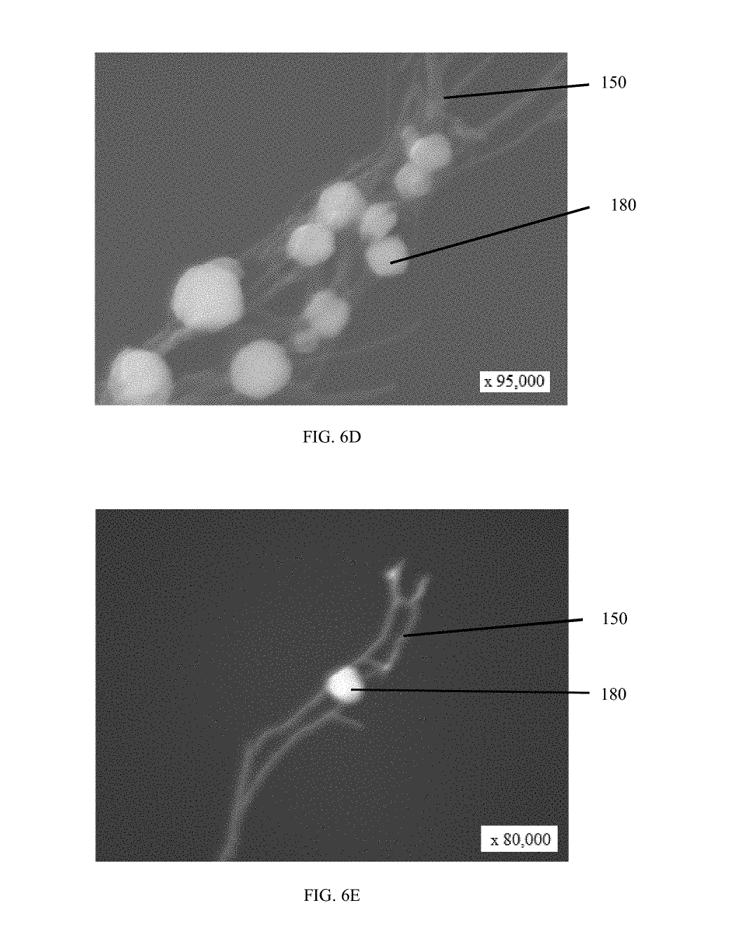

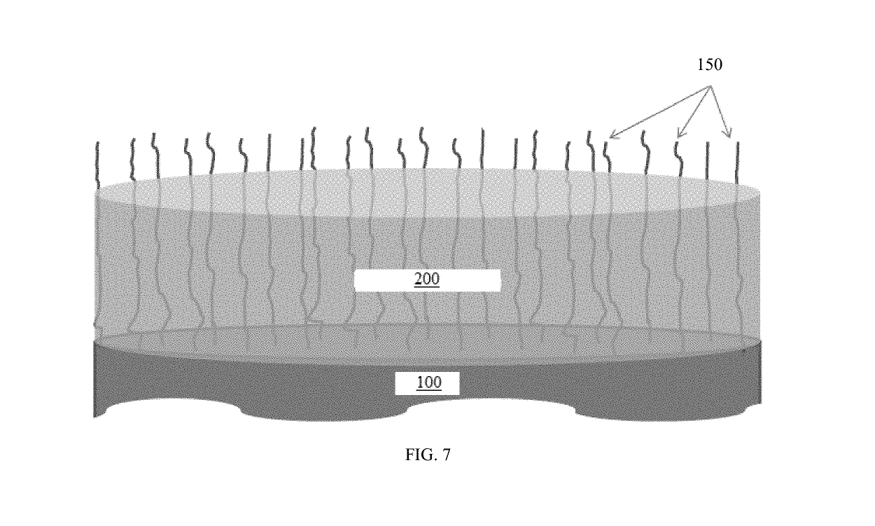

FIG. 3 illustrates the infiltration of a metal or metal alloy into the spaces among carbon nanotubes grown on a substrate; FIG. 4 illustrates the deposition of the metal or metal alloy in the spaces among carbon nanotubes; and FIG. 5 illustrates the formation of a coating on a substrate surface. FIGS. 6A-6E are SEM images of a composite comprising a metal or metal alloy infiltrated into the spaces among aligned carbon nanotubes. As shown in these figures, metal ions 170 diffuse into the spaces among carbon nanotubes 150. The ions 170 accumulate and form metal particles 180. The formed particles 180 merge and form a coating 200. Advantageously, the coating 200 is uniform and there are no gaps between particles.

The polymeric can be disposed into the spaces among carbon nanotubes by melting the polymeric material and infiltrating the melted polymeric material into the spaces among the carbon nanotubes. Suitable polymeric material includes those described herein in the context of polymer substrate. Alternatively, the substrate surface with the nanotubes grown thereon can be exposed to a monomer composition or an oligomer composition, and the monomers or the oligomers can be polymerized forming the polymeric material filling the spaces among the carbon nanotubes.

To further adjust the surface properties of the coatings, the polymeric or the metallic material can be partially removed exposing the second end of the carbon nanotubes. Because the carbon nanotubes are usually hydrophobic, the hydrophobicity of the coating containing the exposed carbon nanotubes can be improved. The method of partially removing the polymeric or metallic material is not particularly limited and includes chemical etching using chemicals such as a base or an acid to remove metals/metal alloys and organic solvents to remove polymeric materials. Suitable acids include HCl, HNO₃, HF or the like. Other known etching agents can also be used. The exposed length of the carbon nanotubes can be controlled by adjusting the etching time and the etching composition.

If desirable,the exposed carbon nanotubes can be further functionalized with a hydrophobic or hydrophilic group to customize the surface properties of the coating for different applications. The functional groups include carboxy, epoxy, ether, ketone, amine, hydroxy, alkoxy, alkyl, lactone, aryl, functionalized polymeric or oligomeric groups, or a combination comprising at least one of the forgoing functional groups.

The thickness of the coating can be from about 10 microns to about 1.5 centimeters, specifically about 10 microns to about 10 mm, more specifically about 50 microns to about 5 mm. In an embodiment, the coating is continuous and does not have voids, microvoids, fractures, or other defects, including pinholes and the like. The carbon nanotubes are present in an amount of about 1 wt. % to about 90 wt. %, about 1 wt. % to about 30 wt. %, about 1 wt. % to about 20 wt. %, about 30 wt. % to about 90 wt. %, or about 35 wt. % to about 90 wt. % based on the total weight of the coating.

Patterning the coating surface is feasible with the chemical vapor deposition of carbon nanotubes. By controlling the area of carbon nanotubes growth with catalyst and surface treatment, the final coating can be designed to different patterns. The coating formed on the substrate can completely cover the substrate or a surface of the substrate.

The coatings provide protection against corrosion of different metals, alloys, and polymeric materials, and are useful for a wide variety of applications including but are not limited to aerospace, automotive, oil and gas, and marine applications.

In an embodiment, the coated article is a downhole element and the coating provides protection to equipment used in the drilling, evaluation, completion and production of oil and gas. In exemplified embodiments, the coating can be applied in part or completely to articles including different oilfield or down-hole elements such as, for example, a sub surface safety valve, a pipe, piston, shaft, ESP pump, drilling bit, a packer element, a blow out preventer element, a submersible pump motor protector bag, a blow out preventer element, a sensor protector, a sucker rod, an O-ring, a T-ring, a gasket, a pump shaft seal, a tube seal, a valve seal, a seal for a drilling motor, or a seal for a drilling bit.

When coated with the coating, these articles and elements have improved mechanical properties and can be used under challenging conditions such as those experienced in undersea or sub-terrain applications. A method of protecting an article from a downhole environment comprises growing carbon nanotubes on a surface of a substrate via a chemical vapor deposition process; the carbon nanotubes having a first end formed on the surface of the substrate and a second end extending away from the substrate; filling the spaces among the carbon nanotubes with a metallic material or a polymeric material forming a coated article; and exposing the coated article to a downhole environment. The downhole environment comprises one or more of the following: a brine; a hydrocarbon; abrasive particles, or an elevated temperature up to about 670° F., up to about 650° F., or up to about 600° F., or greater than 300° F. to less than about 670° F. The brine includes monovalent cations, polyvalent cations, or a combination comprising at least one of the foregoing. The brine can be acidic, basic, or neutral.

Further included in this disclosure are the following specific embodiments, which do not necessarily limit the claims.

Embodiment 1. A method of forming a composite, the method comprising: growing carbon nanotubes on a surface of a substrate via a chemical vapor deposition process; the carbon nanotubes having a first end formed on the surface of the substrate and a second end extending away from the substrate; and filling the spaces among the carbon nanotubes with a metallic material or a polymeric material forming the composite.

Embodiment 2. The method of Embodiment 1, wherein the filling comprises filling the spaces among the carbon nanotubes with the metallic material by a pulsed electrochemical deposition.

Embodiment 3. The method of Embodiment 2, wherein the metallic material comprises a metal, an alloy of the metal, or a combination comprising at least one of the foregoing; wherein the metal comprises Ni, Cu, Ag, Au, Sn, Fe, In, W, Ti, Co, Al, Cr, or Mo.

Embodiment 4. The method of Embodiment 2 or Embodiment 3, wherein the metallic material comprises nickel or a nickel alloy.

Embodiment 5. The method of Embodiment 1, wherein the filing comprises melting the polymeric material and infiltrating the melted polymeric material into the spaces among the carbon nanotubes.

Embodiment 6. The method of any one of Embodiments 1 to 5, further comprising removing a portion of the metallic material or the polymeric material to expose the second ends of the carbon nanotubes.

Embodiment 7. The method of Embodiment 6, wherein the metallic material or the polymeric material is removed by etching.

Embodiment 8. The method of Embodiment 6 or Embodiment 7, further comprising grafting a hydrophobic or a hydrophilic functional group onto the exposed second end of the carbon nanotubes.

Embodiment 9. The method of any one of Embodiments 1 to 8, wherein the substrate comprises a metal; a ceramic material; a polymer, or a combination comprising at least one of the foregoing.

Embodiment 10. The method of any one of Embodiments 1 to 9, wherein the filling comprises filling the spaces among the carbon nanotubes with a metallic material or a polymeric material thus forming a coating having a thickness of about 10 microns to about 1.5 centimeters.

Embodiment 11. The method of any one of Embodiments 1 to 10, wherein the carbon nanotubes are present in an amount of about 1 wt. % to about 90 wt. % based on the total weight of the coating.

Embodiment 12. A composite comprising: a substrate having a surface that is configured for exposure to a well fluid; and a coating disposed on the surface of the substrate; the coating comprising carbon nanotubes grown on the surface of the substrate, the carbon nanotubes having a first end formed on the surface of the substrate and a second end extending away from the substrate; and a metallic or polymeric material filled in the spaces among the carbon nanotubes.

Embodiment 13. The composite of Embodiment 12, wherein the substrate comprises a metal; a ceramic material; a polymer, or a combination comprising at least one of the foregoing.

Embodiment 14. The composite of Embodiment 12 or Embodiment 13, wherein the metallic material comprises a metal, an alloy of the metal, or a combination comprising at least one of the foregoing; wherein the metal comprises Ni, Cu, Ag, Au, Sn, Fe, In, W, Ti, Co, Al, Cr, or Mo.

Embodiment 15. The composition of any one of Embodiments 12 to 14, wherein the metallic material comprises nickel or a nickel alloy.

Embodiment 16. The composite of any one of Embodiments 12 to 15, wherein the carbon nanotubes are present in an amount of about 1 wt. % to about 90 wt. % based on the total weight of the coating.

Embodiment 17. The composite of any one of Embodiments 12 to 16, wherein the composite is a downhole article.

Embodiment 18. A method of protecting an article from a downhole environment, the method comprising: growing carbon nanotubes on a surface of the article via a chemical vapor deposition process; the carbon nanotubes having a first end formed on the surface of the substrate and a second end extending away from the substrate; filling the spaces among the carbon nanotubes with a metallic material or a polymeric material forming a coated article; and exposing the coated article to a downhole environment.

Embodiment 19. The method of Embodiment 18, wherein the downhole environment comprises a brine, a hydrocarbon, abrasive particles, or an elevated temperature of up to about 670° F.

Embodiment 20. The method of Embodiment 18 or Embodiment 19, wherein the filling comprises filling the spaces among the carbon nanotubes with the metallic material by a pulsed electrochemical deposition.

The use of the terms “a” and “an” and “the” and similar referents in the context of describing the invention (especially in the context of the following claims) are to be construed to cover both the singular and the plural, unless otherwise indicated herein or clearly contradicted by context. “Or” means “and/or.” The modifier “about” used in connection with a quantity is inclusive of the stated value and has the meaning dictated by the context (e.g., it includes the degree of error associated with measurement of the particular quantity). As used herein, the size or average size of the particles refers to the largest dimension of the particles and can be determined by high resolution electron or atomic force microscope technology.

All references cited herein are incorporated by reference in their entirety. While typical embodiments have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

What is claimed is:

1. A method of forming a composite, the method comprising:
growing carbon nanotubes on a surface of a substrate via a chemical vapor deposition process; the carbon nanotubes having a first end formed on the surface of the substrate and a second end extending away from the substrate; and
filling the spaces among the carbon nanotubes with a metallic material or a polymeric material forming the composite.

2. The method of claim 1, wherein the filling comprises filling the spaces among the carbon nanotubes with the metallic material by a pulsed electrochemical deposition.

3. The method of claim 2, wherein the metallic material comprises a metal, an alloy of the metal, or a combination comprising at least one of the foregoing; wherein the metal comprises Ni, Cu, Ag, Au, Sn, Fe, In, W, Ti, Co, Al, Cr, or Mo.

4. The method of claim 2, wherein the metallic material comprises nickel or a nickel alloy.

5. The method of claim 1, wherein the filing comprises melting the polymeric material and infiltrating the melted polymeric material into the spaces among the carbon nanotubes.

6. The method of claim 1, further comprising removing a portion of the metallic material or the polymeric material to expose the second ends of the carbon nanotubes.

7. The method of claim 6, wherein the metallic material or the polymeric material is removed by etching.

8. The method of claim 6, further comprising grafting a hydrophobic or a hydrophilic functional group onto the exposed second end of the carbon nanotubes.

9. The method of claim 1, wherein the substrate comprises a metal; a ceramic material; a polymer, or a combination comprising at least one of the foregoing.

10. The method of claim 1, wherein the filling comprises filling the spaces among the carbon nanotubes with a metallic material or a polymeric material thus forming a coating having a thickness of about 10 microns to about 1.5 centimeters.

11. The method of claim 10, wherein the carbon nanotubes are present in an amount of about 1 wt. % to about 90 wt. % based on the total weight of the coating.

12. A composite comprising:
a substrate having a surface that is configured for exposure to a well fluid; and
a coating disposed on the surface of the substrate;
the coating comprising
carbon nanotubes grown on the surface of the substrate, the carbon nanotubes having a first end formed on the surface of the substrate and a second end extending away from the substrate; and
a metallic or polymeric material filled in the spaces among the carbon nanotubes.

13. The composite of claim 12, wherein the substrate comprises a metal; a ceramic material; a polymer, or a combination comprising at least one of the foregoing.

14. The composite of claim 12, wherein the metallic material comprises a metal, an alloy of the metal, or a combination comprising at least one of the foregoing; wherein the metal comprises Ni, Cu, Ag, Au, Sn, Fe, In, W, Ti, Co, Al, Cr, or Mo.

15. The composition of claim 12, wherein the metallic material comprises nickel or a nickel alloy.

16. The composite of claim 12, wherein the carbon nanotubes are present in an amount of about 1 wt. % to about 90 wt. % based on the total weight of the coating.

17. The composite of claim 12, wherein the composite is a downhole article.

18. A method of protecting an article from a downhole environment, the method comprising:
growing carbon nanotubes on a surface of the article via a chemical vapor deposition process; the carbon nanotubes having a first end formed on the surface of the substrate and a second end extending away from the substrate;
filling the spaces among the carbon nanotubes with a metallic material or a polymeric material forming a coated article; and
exposing the coated article to a downhole environment.

19. The method of claim 18, wherein the downhole environment comprises a brine, a hydrocarbon, abrasive particles, or an elevated temperature of up to about 670° F.

20. The method of claim 18, wherein the filling comprises filling the spaces among the carbon nanotubes with the metallic material by a pulsed electrochemical deposition.
